(19) United States
(12) Patent Application Publication
(10) Pub. No.: US 2004/0132299 A1
(43) Pub. Date: Jul. 8, 2004

(54) Method for depositing lead-free tin alloy

(75) Inventors: Motoaki Matsuda, Kumamoto (JP); Masahiro Ibe, Kumamoto (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 10/738,043

(22) Filed: Dec. 18, 2003

(30) Foreign Application Priority Data
Dec. 25, 2002 (JP) 2002-375604

(51) Int. Cl. H01L 21/302; H01L 21/461

(52) U.S. Cl. 438/689

(57) ABSTRACT

In accordance with the present invention, there is provided a method for depositing a lead-free tin alloy on a substrate. The substrate includes an external lead portion of a semiconductor device. The substrate is contacted with an electrolyte composition for depositing the lead-free tin alloy. Current is cyclically passed in a first direction through the electrolyte composition during ON-duty cycle portions to deposit the lead-free tin alloy on the substrate. The passing of current in the first direction through the electrolyte composition is cyclically prevented during OFF-duty cycle portions.

### BACKGROUND OF THE INVENTION

1. Field of the Invention

The present invention relates to methods for depositing a lead-free tin alloy. More particularly, the present invention relates to a method for depositing lead-free tin alloy with resistance to abnormal deposition and local deposition.

2. Description of Related Art

JP61-194196 discloses a method for depositing a tin lead-alloy by electroplating using an organic sulfonic acid bath. It teaches that intermittently interrupting or reversing a direction of a current passing through an electrolyte composition provides deposit with increased resistance to whisker formation. The current density is 2 A/dm². A cycle portion during which the current passes through the electrolyte composition is not longer than 80 seconds and preferably ranges from 20 seconds to 50 seconds. The other cycle portion is not shorter than 3 seconds and preferably ranges from 5 seconds to 20 seconds.

### SUMMARY OF THE INVENTION

As mentioned above, according to the known electroplating process, the other cycle portion is not shorter than 3 seconds. If this known process is carried out in depositing a lead-free tin alloy in the form of a tin-bismuth alloy, the following insufficiencies are noted.

Formation of whisker has been and continues to be a growing problem. One cycle consisting of one and the other cycle portions, namely, an ON-OFF cycle, is too long to suppress formation of whisker effectively (one insufficiency). Local deposition has been and continues to be a growing problem. When the current is interrupted, electroless deposition of bismuth appears at or near both anode and cathode. As the electroless deposition of bismuth exhibits high ionization tendency, even deposition is difficult to accomplish (another insufficiency).

While not whishing to be bounded by theory, formation of whisker is believed to be based upon dendrite growth. Formation of whisker has been often found in the surface of deposition by electroplating with uninterrupted current. The structure of crystal, the anisotropy of crystal growth and the affinity within the surface of cathode cause dendrite precursors to appear. Current for electroplating passes through portions of the dendrite precursors and is localized. Exposure to the high density of current accelerates deposition at the portions, causing dendrite growth. It is well known that whiskers are major causes of short circuit and a need remains for a method for depositing a lead-free tin alloy without formation of whiskers for yielding high quality of products.

Density of metal ions near the surface of cathode drops during the accelerated deposition, forming an electric double layer, causing an increase in density of metal ions at the dendrite precursors separated from the cathode surface, causing local concentration of electroplated deposition.

The present invention aims at preventing formation of whisker within the surface of electroplated deposition of a lead-free tin alloy. An object of the present invention therefore is to provide a method for depositing a lead-free tin alloy without formation of whisker and local concentration of electroplated deposition. A specific object of the present invention is to provide a method for depositing a lead-free tin alloy by suppressing formation of an electric double layer during electroplating.

According to one implementation of the present invention, there is provided a method for depositing a lead-free tin alloy on a substrate, comprising:

contacting the substrate with an electrolyte composition for depositing the lead-free tin alloy;

cyclically passing a current in a first direction through the electrolyte composition during ON-duty cycle portions to deposit the lead-free tin alloy on the substrate; and

cyclically preventing the passing of current in the first direction through the electrolyte composition during OFF-duty cycle portions.

### BRIEF DESCRIPTION OF THE DRAWINGS

FIG. 1 is a sectional view of a portion of electroplating equipment for carrying out a method for depositing a lead-free tin alloy according to the present invention.

FIG. 2 is a diagram of varying a command signal indicative of the magnitude and direction of current passing through an electrolyte composition with time, illustrating one implementation of the present invention.

FIG. 3 is a diagram of varying another command signal indicative of the magnitude and direction of current passing through electrolyte composition with time, illustrating another implementation of the present invention.

FIG. 4 is a table containing results of experiments.

FIG. 5 plots the results of experiments.

### DETAILED DESCRIPTION OF THE INVENTION

As used throughout this specification, the following abbreviations shall have the following meanings, unless the context clearly indicates otherwise: g=gram; L=liter; mL=milliliter; ° C.=degrees Centigrade; and A/dm²=amperes per square decimeter. The terms “depositing” and “electroplating” are used interchangeably throughout this specification. All numerical ranges are inclusive.

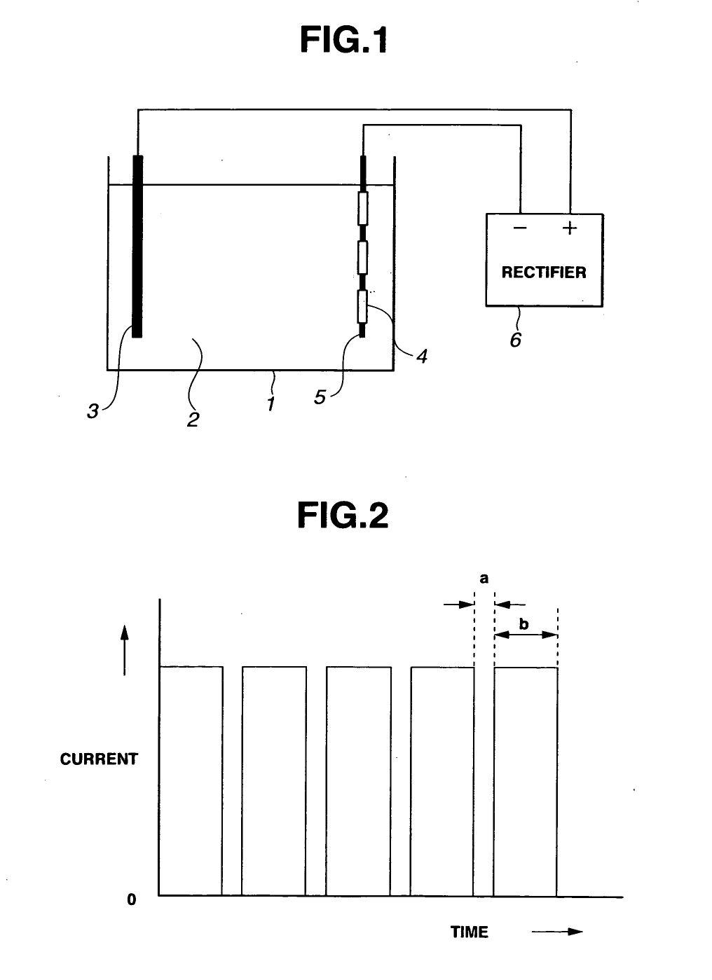

Any various types of electroplating equipment available in the market may be used to carry out a method for depositing a lead-free tin alloy according to the present invention without any substantial changes or modifications. With reference to FIG. 1, the reference numeral 1 denotes an electroplating bath containing an electrolyte composition 2 for depositing a lead-free tin alloy on a substrate. Immersed into the electrolyte composition 2 are an anode 3 and a cathode to which a semiconductor device 4 including an external lead portion 5 is connected. In this case, the external lead portion 5 serves as the cathode and is the substrate to be electroplated. The anode 3 and cathode are connected to a rectifier 6. In response to a command signal (see FIG. 2), the rectifier 6 can cyclically pass a current in one direction through the electrolyte composition 2 between the anode 3 and cathode to deposit the lead-free tin alloy on the external lead portion 5 during ON-duty cycle portions. Naturally, the rectifier 6 can cyclically prevent or suspend the passing of the current during OFF-duty cycle portions.

The external lead portion 5 is just one example of the substrate to be electroplated. The substrate may be selected from electronic components. The electronic components are selected from lead frames, semiconductor packages, connectors, contacts, chip capacitors or plastics. Suitable plastics include plastic laminates, such as printing wiring boards, particularly copper clad printed wiring boards.

The substrate may be contacted with the electrolyte composition in any manner known in the art.

In accordance with one implementation of the present invention, as bath components of an alkanol sulfonic acid bath, an electrolyte composition for electroplating of tin-bismuth alloy is prepared. The electrolyte composition comprises an alkanol sulfonic acid with a density of 200∓25 g/L, a tin alkanol sulfonic acid with a density of 45∓5 g/1L, a bismuth alkanol sulfonic acid with a density of 1.1∓0.6 g/L, and a PF-05M (a trade name of chemical supplied by ISHIHARA CHEMICAL CO., LTD). The electrolyte composition is maintained at a temperature of 40∓5° C. During ON-duty cycle portions, the current density used for the electroplating is not greater than 5 A/dm² and preferably at 4.5 A/dm². In accordance with the one implementation of the present invention, the current with the above density is cyclically passed in one or first direction through the electrolyte composition during ON-duty cycle portions to deposit the tin-bismuth alloy on the external lead portion. In order to suppress drop in the density of metal ions in the neighborhood of the surface of cathode, the passing of the current in the first direction is cyclically prevented during OFF-duty cycle portions by cyclically interrupting supply of current to the electrolyte composition during the OFF-duty cycle portions.

With reference now to FIG. 2, an ON-OFF cycle consists of an ON-duty cycle portion and the following OFF-duty cycle portion. The frequency is in the range of 1 cycle in one second to 5 cycles in one second. A ratio, namely, an a/b ratio, of the OFF-duty cycle portion a of each ON-OFF cycle to the ON-duty ratio b thereof is not less than 0.2. In order to carry out the electroplating within a reasonable period of time, the a/b ratio is preferably 0.3.

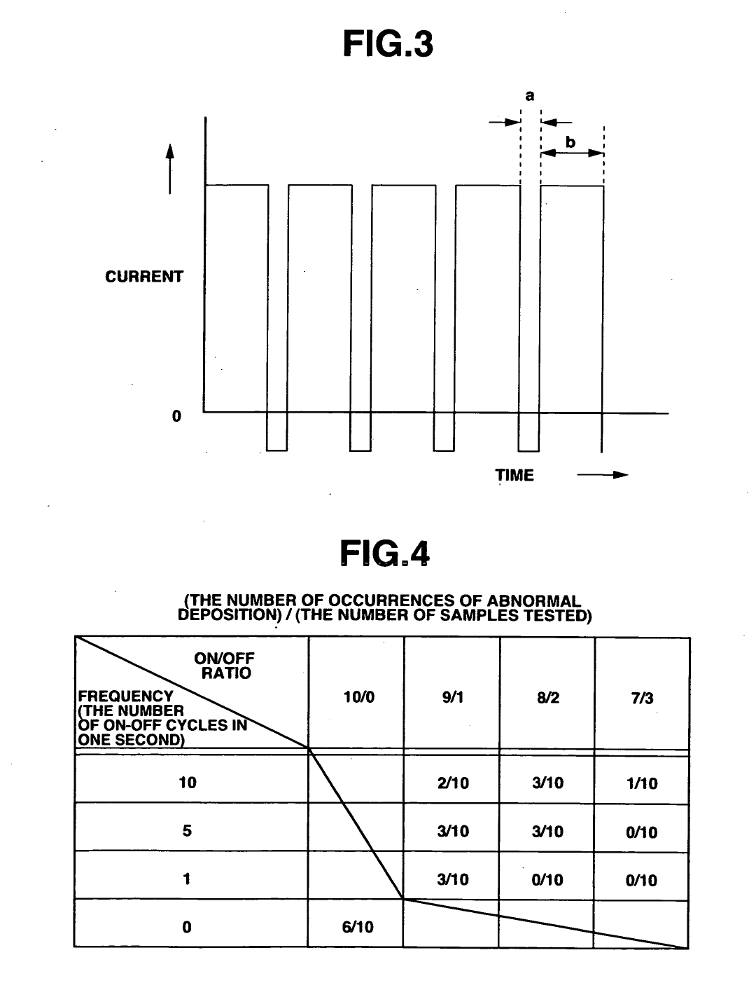

With reference now to FIG. 3, another implementation of the present invention is described. This implementation is substantially the same as the above-described implementation except the manner of cyclically preventing the passing of current in the first direction during OFF-duty cycle portions. In this implementation, in order to more effectively suppress drop in the density of metal ions in the neighborhood of the surface of cathode, the passing of the current in the first direction is cyclically prevented during OFF-duty cycle portions by cyclically passing a current in a second direction opposite to the first direction through the electrolyte composition during the OFF-duty cycle portions. This can be accomplished by cyclically establishing inversed potential state during the OFF-duty cycle portions to reverse the direction of current passing through the electrolyte composition.

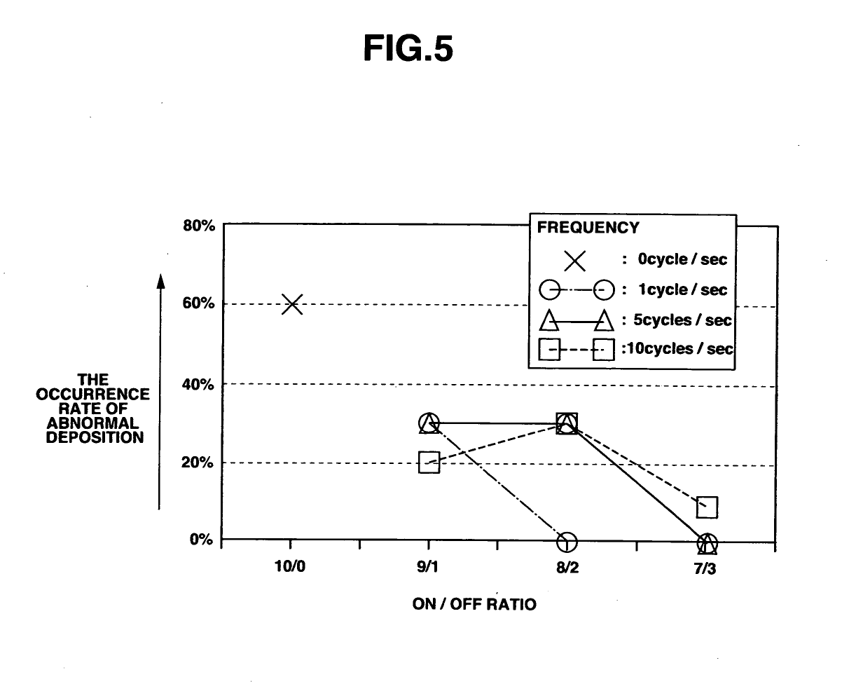

Ten samples or examples in control procedure of current illustrated in FIG. 2 were tested or evaluated using the above mentioned tin-bismuth (Sn—Bi) bath. FIGS. 4 and 5 contain the results of electroplating.

Example #1: an ON/OFF ratio=8/2, that is, the a/b ratio is 2/8 (=0.25); and the frequency=1 cycle in one second. The result of electroplating: the occurrence rate of abnormal deposition=0/10 (=0%).

Example #2: the ON/OFF ratio=7/3, that is, the a/b ratio is 3/7 (≈0.43); and the frequency=5 cycles in one second. The result of electroplating: the occurrence rate of abnormal deposition=0/10 (=0%).

Example #3: the ON/OFF ratio=7/3, that is, the a/b ratio is 3/7 (≈0.43); and the frequency=5 cycles in one second. The result of electroplating: the occurrence rate of abnormal deposition=0/10 (=0%).

Less Preferred Example #4: the ON/OFF ratio=7/3, that is, the a/b ratio is 3/7 (≈0.43); and the frequency=10 cycles in one second. The result of electroplating: the occurrence rate of abnormal deposition=1/10 (=10%).

Less Preferred Example #5: the ON/OFF ratio=8/2, that is, the a/b ratio is 2/8 (=0.25); and the frequency=5 cycles in one second. The result of electroplating: the occurrence rate of abnormal deposition=3/10 (=30%).

Less Preferred Example #6: the ON/OFF ratio=8/2, that is, the a/b ratio is 2/8 (=0.25); and the frequency=5 cycles in one second. The result of electroplating: the occurrence rate of abnormal deposition=3/10 (=30%).

Less Preferred Example #7: the ON/OFF ratio=9/1, that is, the a/b ratio is 1/9 (≈0.11); and the frequency=1 cycle in one second. The result of electroplating: the occurrence rate of abnormal deposition=3/10 (=30%).

Less Preferred Example #8: the ON/OFF ratio=9/1, that is, the a/b ratio is 1/9 (≈0.11); and the frequency=5 cycles in one second. The result of electroplating: the occurrence rate of abnormal deposition=3/10 (=30%).

Less Preferred Example #9: the ON/OFF ratio=9/1, that is, the a/b ratio is 1/9 (≈0.11); and the frequency=10 cycles in one second. The result of electroplating: the occurrence rate of abnormal deposition=2/10 (=20%).

Comparative Example #10: the ON/OFF ratio=10/0, that is, the a/b ratio is 0/10 (=0); and the frequency=0 cycle in one second. The result of electroplating: the occurrence rate of abnormal deposition=6/10 (=60%).

The lead-free tin alloy, which may be used in the present invention, is not limited to the above-mentioned tin-bismuth alloy. The lead-free tine alloy includes, in combination with tin, a second metal selected from a group consisting of copper, silver, and zinc.

For electroplating a tin-copper alloy, a tin-copper (Sn—Cu) electroplating is carried out using an alkanol sulfonic acid bath. An electrolyte composition for electroplating of tin-copper alloy comprises an alkanol sulfonic acid, a tin alkanol sulfonic acid, a copper alkanol sulfonic acid, and a T-130CU (a trade name of chemical supplied by ISHIHARA CHEMICAL CO., LTD).

For electroplating a tin-silver alloy, a tin-silver (Sn—Ag) electroplating is carried out using an alkanol sulfonic acid bath. An electrolyte composition for electroplating of tin-silver alloy comprises an alkanol sulfonic acid, a tin alkanol sulfonic acid, a silver alkanol sulfonic acid, and a HIS-008 (a trade name of chemical supplied by ISHIHARA CHEMICAL CO., LTD).

Although the present invention and its advantage have been described in detail, it should be understood that various changes, substitutions and alternations could be made herein without departing from the sprit and scope of the invention.

The present application claims the priority of Japanese Patent Application No. 2002-375604, filed Dec. 25, 2002, the disclosure of which is hereby incorporated by reference in its entirety.

What is claimed is:

1. A method for depositing a lead-free tin alloy on a substrate, comprising:
contacting the substrate with an electrolyte composition for depositing the lead-free tin alloy;
cyclically passing a current in a first direction through the electrolyte composition during ON-duty cycle portions to deposit the lead-free tin alloy on the substrate; and
cyclically preventing the passing of current in the first direction through the electrolyte composition during OFF-duty cycle portions.

2. The method as claimed in claim 1, wherein the substrate includes an external lead portion of a semiconductor device.

3. The method as claimed in claim 1, wherein the cyclically preventing includes:
cyclically interrupting supply of current to the electrolyte composition during the OFF-duty cycle portions.

4. The method as claimed in claim 1, wherein the cyclically preventing includes:
cyclically passing a current in a second direction opposite to the first direction through the electrolyte composition during the OFF-duty cycle portions.

5. The method as claimed in claim 1, wherein a ratio of the OFF-duty cycle portion of each cycle to the ON-duty cycle portion thereof is not less than 0.2.

6. The method as claimed in claim 1, wherein the cycle is repeated at a frequency in the range from 1 cycle in one second to 5 cycles in one second.

7. The method as claimed in claim 1, wherein the current passing in the first direction has a current density not greater than 5 A/dm².

8. The method as claimed in claim 1, wherein the lead-free tin alloy includes, in combination with tin, a second metal selected from a group consisting of bismuth, copper, silver, and zinc.
